(19) United States
(12) Patent Application Publication
(10) Pub. No.: US 2024/0418211 A1
(43) Pub. Date: Dec. 19, 2024

(54) ROLLER RETAINER, ROLLER-RETAINER CONNECTED BODY, CROSS ROLLER GUIDE, AND STAGE DEVICE

(71) Applicant: NuFlare Technology, Inc., Yokohama-shi (JP)

(72) Inventors: Yasutaka SATO, Hachioji-shi (JP); Kiminobu AKENO, Yokohama-shi (JP); Yuji ABE, Yokohama-shi (JP)

(73) Assignee: NuFlare Technology, Inc., Yokohama-shi (JP)

(21) Appl. No.: 18/734,011

(22) Filed: Jun. 5, 2024

(30) Foreign Application Priority Data
Jun. 16, 2023 (JP) 2023-099407

(51) Int. Cl. F16C 29/04; F16C 33/50

(52) U.S. Cl. CPC F16C 29/041; F16C 33/50

(57) ABSTRACT

In one embodiment, a roller-retainer connected body is formed by connecting a plurality of roller retainers each accommodating a roller to one another. Each roller retainer includes a base part, a first block provided at one end of the base part, and a second block provided at the other end of the base part. Each roller retainer accommodates a roller in a roller accommodating part between the first block and the second block, and has a connector provided on each of an outer end face of the first block and an outer end face of the second block. The connectors of the plurality of roller retainers are connected to each other such that the rollers accommodated in the roller accommodating parts of the plurality of roller retainers rotate on different axes including rotation around a connecting axis.

### CROSS REFERENCE TO RELATED APPLICATION

This application is based upon and claims benefit of priority from the Japanese Patent Application No. 2023-099407, filed on Jun. 16, 2023, the entire contents of which are incorporated herein by reference.

### FIELD

The present invention relates to a roller retainer, a roller-retainer connected body, a cross roller guide, and a stage device.

### BACKGROUND

A charged-particle-beam writing apparatus writes a predetermined pattern on a mask while a stage device is adjusting the position of the mask. A linear motion stage used as the stage device includes a guide rail, a plurality of rollers, and a long plate-like holder (roller gauge) holding the plurality of rollers, and uses lubricant for the purpose of reducing wear of these components.

If the viscosity of the lubricant is high, minute vibration occurs when the rollers go over the lubricant. This lowers the accuracy of measuring the stage position, leading to a problem in that the writing accuracy is deteriorated. Therefore, the lubricant used in the stage device is preferably lubricant having a low viscosity, such as vacuum oil.

However, it is difficult to allow the vacuum oil (low-viscosity lubricant) to stay between the guide rail and the rollers for a long time, and the oil supply frequency tends to be high. In order to reduce the oil supply frequency, in a known measure, a pocket for retaining oil is provided in the roller gauge. However, to provide the oil retention pocket, the roller gauge is increased in cross-sectional area (thickness) and increased in rigidity. When the rigidity of the roller gauge is high, proper contact between the guide rail and the roller is hindered. This leads to a problem in that an unintended gap is created between the guide rail and the rollers, affecting the orientation stability of the stage and the rigidity of the stage itself.

### BRIEF DESCRIPTION OF THE DRAWINGS

FIG. 1 schematically illustrates the configuration of a charged-particle-beam writing apparatus having a stage device according to an embodiment of the present invention.

FIG. 2 is a perspective view illustrating an example configuration of the stage device.

FIG. 3 schematically illustrates the configuration of the stage device.

FIG. 4 is a perspective view of a roller retainer.

FIG. 5 is a view from an arrow A direction in FIG. 4.

FIG. 6 is a perspective view of the roller retainer accommodating a roller.

FIG. 7 is a diagram illustrating a state in which the roller retainers are connected.

FIG. 8 is a diagram illustrating rotation of the roller retainers.

FIG. 9 is a sectional view of a cross roller guide.

FIG. 10A is a perspective view of a roller retainer according to another embodiment, and FIG. 10B is a perspective view of a connecting part.

FIG. 11 is a diagram illustrating a method for connecting the roller retainers.

### DETAILED DESCRIPTION

In one embodiment, a roller-retainer connected body is formed by connecting a plurality of roller retainers each accommodating a roller to one another. Each roller retainer includes a base part, a first block provided at one end of the base part, and a second block provided at the other end of the base part. Each roller retainer accommodates a roller in a roller accommodating part between the first block and the second block, and has a connector provided on each of an outer end face of the first block and an outer end face of the second block. The connectors of the plurality of roller retainers are connected to each other such that the rollers accommodated in the roller accommodating parts of the plurality of roller retainers rotate on different axes including rotation around a connecting axis.

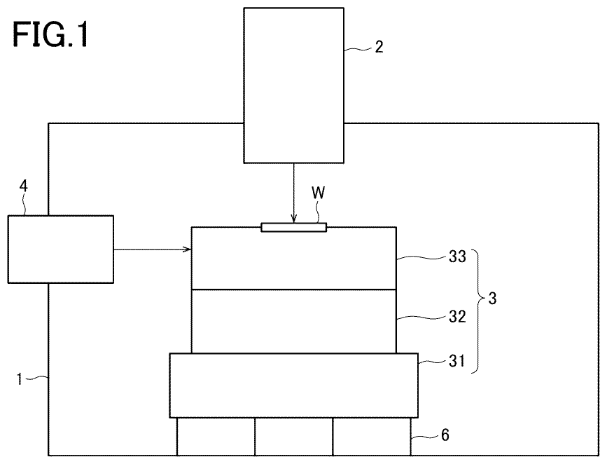

FIG. 1 schematically illustrates an example configuration of a charged-particle-beam writing apparatus having a stage device 3 according to an embodiment of the present invention. The charged-particle-beam writing apparatus illustrated in FIG. 1 writes a predetermined pattern by irradiating a processing target (mask W) with an electron beam, for example. Besides the writing apparatus, this embodiment may be an apparatus, such as an exposure apparatus, an electron microscope, or an optical microscope, that irradiates a processing target with an electron beam (charged particle beam) or light. Hence, the processing target may be a semiconductor substrate or the like, besides the mask.

As illustrated in FIG. 1, the charged-particle-beam writing apparatus includes a chamber 1, an electron source 2, a stage device 3, and a laser length measuring unit 4. The chamber 1 is evacuated and accommodates the stage device 3. The electron source 2 is provided on the ceiling of the chamber 1 and irradiates the mask W with the electron beam. The stage device 3 is supported by a plurality of spacers 6.

The stage device 3 includes an XY stage 31, a Z stage 32, and a top stage 33, and adjusts the position of the mask W placed on the top stage 33.

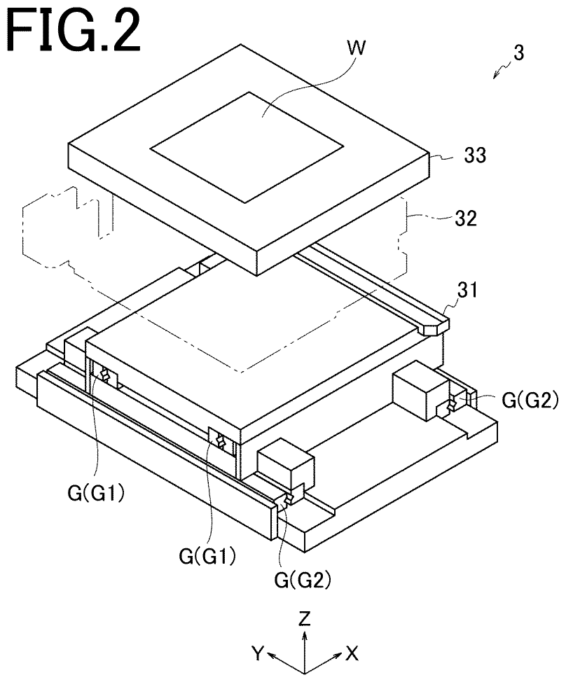

As illustrated in FIG. 2, the XY stage 31 has cross roller guides G extending in the X-axis and Y-axis directions, and moves the Z stage 32 and the top stage 33 in the X-axis direction and the Y-axis direction. More specifically, the Z stage 32 and the top stage 33 can be moved in the X-axis direction by the cross roller guides G1. The Z stage 32 and the top stage 33 can be moved in the Y-axis direction by the cross roller guides G2.

The Z stage 32 can move the top stage 33 in the Z-axis direction. This makes it possible to move the top stage 33 in three axis directions (X, Y, and Z) to dispose the mask W at a desired position.

The laser length measuring unit 4 (see FIG. 1) measures the position of the top stage 33. The position of the top stage 33 is feedback-controlled on the basis of the measurement result obtained by the laser length measuring unit 4. While the position control of the top stage 33 is being performed, an electron beam is radiated on the mask W to write a pattern.

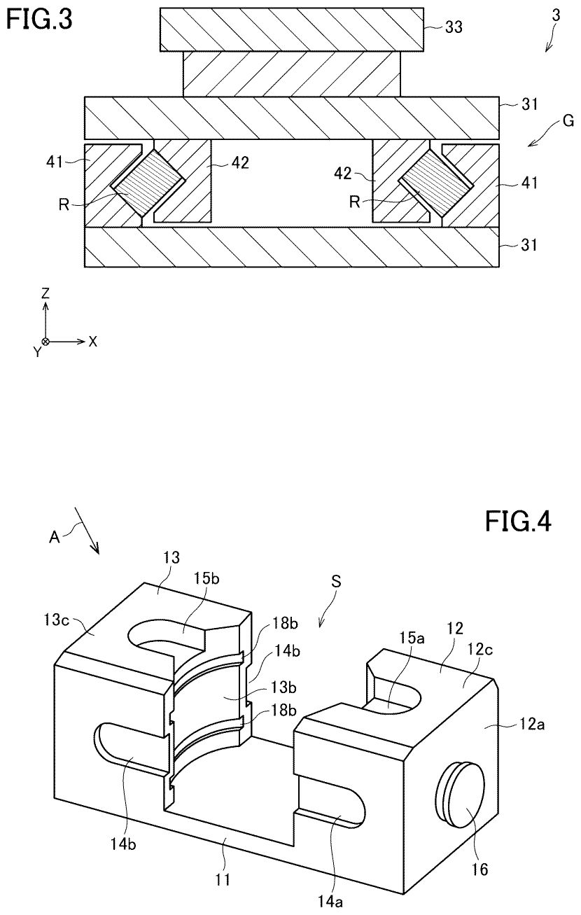

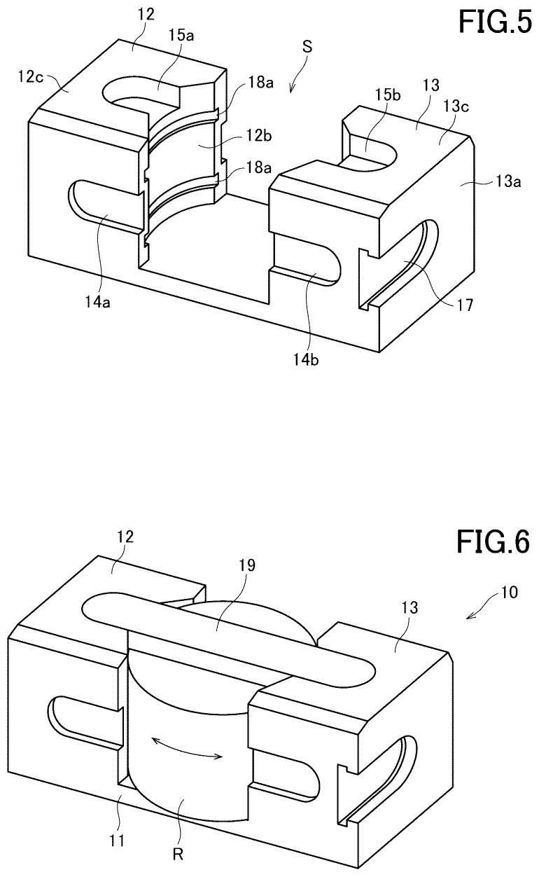

FIG. 3 is a view from a Y direction in FIG. 2. In FIG. 3, the Z stage 32 is omitted. The cross roller guides G (G2) each include guide rails 41 and 42, a plurality of rollers R disposed between the guide rail 41 and the guide rail 42, and roller retainers 10 (see FIGS. 4 to 6) for retaining the rollers R. At least two rail sets, each including the guide rails 41 and 42, are provided. The guide rails 41 and 42 have a square column shape, are arranged in parallel, and have V-grooves formed in the opposing surfaces thereof.

The guide rails 41 are connected to the lower part (fixed plate) of the XY stage 31. The guide rails 42 are connected to the upper part (a horizontally movable table) of the XY stage 31. The upper part of the XY stage 31 and the guide rails 42 move in the Y-axis direction when the rollers R roll. The lower part of the XY stage 31 and the guide rails 41 do not move.

As illustrated in FIGS. 4 and 5, the roller retainer 10 includes a plate-like base part 11 having a rectangular shape in plan view, and a first block 12 and a second block 13 provided at both ends of the base part 11 in the longitudinal direction. A region surrounded by the first block 12, the second block 13, and the central part of the base part 11 serves as a roller accommodating part S. Hereinbelow, the longitudinal direction of the base part 11 and the lateral direction of the base part 11 are referred to as a “longitudinal direction” and a “lateral direction”, respectively.

A flanged projection 16 (connector) is provided on an outer end face 12a of the first block 12 in the longitudinal direction. A recess 14a for holding lubricant is formed in an outer side surface of the first block 12 in the lateral direction. One end of the recess 14a is continuous with the roller accommodating part S.

An inner side surface 12b of the first block 12 in the longitudinal direction faces the roller accommodating part S and is curved so as to conform to the outer shape of the roller R. Grooves 18a for holding lubricant are formed in the side surface 12b (inner circumferential surface). The grooves 18a are parallel to the main surface of the base part 11. Although FIG. 5 illustrates an example in which two grooves 18a are formed, the number of grooves 18a may be one or three or more.

A recess 15a to which a fastener 19 (see FIG. 6, described below) is to be attached, is formed in an upper surface 12c of the first block 12.

An engaging groove 17 (connector) having a dovetail groove shape (substantially T-shaped cross section) is formed in an outer end face 13a of the second block 13 in the longitudinal direction, so as to extend in a direction orthogonal to the rotation axis of the roller R. A recess 14b for holding lubricant is formed in an outer side surface of the second block 13 in the lateral direction. One end of the recess 14b is continuous with the roller accommodating part S.

An inner side surface 13b of the second block 13 in the longitudinal direction faces the roller accommodating part S and is curved so as to conform to the outer shape of the roller R. Grooves 18b for holding lubricant are formed in the side surface 13b. The grooves 18b are parallel to the main surface of the base part 11 (the surface orthogonal to the rotation axis of the roller R). Although FIG. 4 illustrates an example in which two grooves 18b are formed, the number of grooves 18b may be one or three or more.

A recess 15b is formed in an upper surface 13c of the second block 13.

As illustrated in FIG. 6, a substantially columnar roller R is disposed in the roller accommodating part S. The width of the base part 11 in the lateral direction is smaller than the diameter of the roller R, so, the side circumferential surface of the roller R protrudes outward from the side surfaces of the first block 12 and the second block 13.

A rod-like fastener 19 is disposed so as to bridge between the first block 12 and the second block 13. One end of the fastener 19 is fitted into the recess 15a, and the fastener 19 and the first block 12 are fastened together with a fastening member, such as a bolt (not illustrated). The other end of the fastener 19 is fitted into the recess 15b, and the fastener 19 and the second block 13 are fastened together with a fastening member, such as a bolt (not illustrated). This way, the roller retainer 10 can retain the roller R. The roller R retained by the roller retainer 10 can rotate (revolve).

When bolts are used as the fastening members for the fasteners 19, bolt insertion holes (not illustrated) penetrating from the recesses 15a and 15b to the lower surface of the base part 11 are formed in the first block 12 and the second block 13, respectively. The ends of the fastener 19 are fixed to the first block 12 and the second block 13 with the bolts inserted through the bolt insertion holes.

The roller retainer 10 and the fastener 19 may be made of resin such as PEEK. For example, the roller retainer 10 can be produced by machining a recess corresponding to the roller accommodating part S, the grooves for holding lubricant, and the like in a resin block having a rectangular-parallelepiped shape. For the material of the roller R, a cemented carbide or the like may be used.

The dimensions of the roller retainer 10 may be determined as appropriate in accordance with the size of the roller R to be used. For example, the base part 11 is approximately 18 mm long in the longitudinal direction, 8 mm long in the lateral direction, and 1 mm thick.

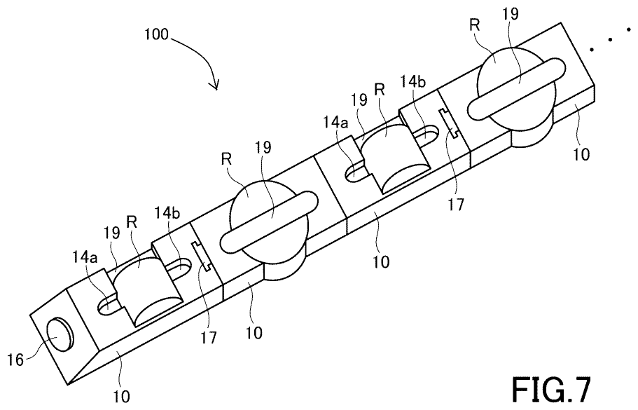

A plurality of roller retainers 10 holding the rollers R are prepared. The projection 16 of one roller retainer 10 is engaged with the engaging groove 17 of another roller retainer 10 to connect the roller retainers 10 to each other. By repeating this, a connected body 100 of the roller retainers 10, as illustrated in FIG. 7, is obtained.

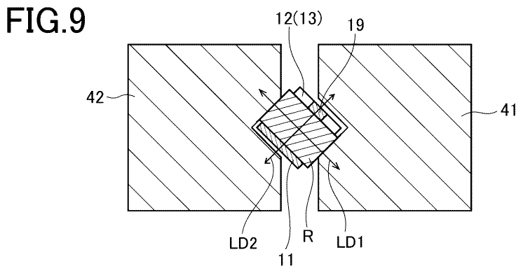

The connected body 100 of the roller retainers 10 is disposed between the V-groove in the guide rail 41 and the V-groove in the guide rail 42. The side circumferential surfaces of the rollers R are in contact with the upper slope of the V-groove in the guide rail 41 and the lower slope of the V-groove in the guide rail 42. Alternatively, the side circumferential surfaces of the rollers R are in contact with the lower slope of the V-groove in the guide rail 41 and the upper slope of the V-groove in the guide rail 42 (see FIG. 9).

FIG. 7 illustrates an example in which the rollers R that are in contact with the upper slope of the V-groove in the guide rail 41 and the lower slope of the V-groove in the guide rail 42 and the rollers R that are in contact with the lower slope of the V-groove in the guide rail 41 and the upper slope of the V-groove in the guide rail 42 are arranged alternately. However, the arrangement method of the rollers R is not limited thereto.

When a force in the traveling axis direction is applied to the upper part of the XY stage 31, the guide rails 42 move in the traveling axis direction. At this time, the rollers R revolve and convey the guide rail 42.

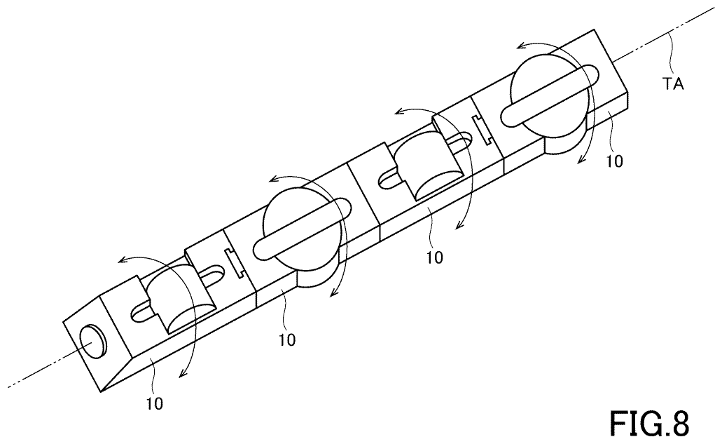

In this embodiment, the projections 16 are engaged with the engaging grooves 17, so that the roller retainers 10 are connected in a row. Thus, as illustrated in FIG. 8, the roller retainers 10 are independently rotatable about the traveling axis TA (the axis in the connecting direction). Furthermore, as illustrated in FIG. 9, the roller retainers 10 are movable (translatable) in a radial load direction LD1. Each roller R rotates on its own axis. Thus, the rollers R accommodated in the roller retainers 10 can rotate about different axes. In order to avoid unintended wear due to contact between the roller retainers 10 and the guide rails, the roller retainers 10 are prevented from moving (translating) in a rotational axis direction LD2 of the rollers R.

The V-groove surface of the guide rail 41 has slight variations in angle and straightness due to the influence of deformation of a rail material occurring during machining, the accuracy of a tool and a machine, and the like. Even when such variation in angle or variation in straightness occurs, the roller retainers 10 rotate about the traveling axis so as to follow the angle of the V-groove surface of the guide rail 41, absorbing the difference in angle between the rollers R and the V-groove surface and maintaining good contact between the rollers R and the V-groove surface. This improves the orientation stability of the stage and stabilizes the rigidity of the stage itself, thus making it possible to eliminate the risk of stopping and vibration of the stage.

Furthermore, even when the machining position of the hole to serve as the roller accommodating part S is displaced from the designed position, because the roller retainer 10 translates in the radial load direction, proper contact between the roller R and the V-groove surface can be achieved.

Furthermore, because the roller retainer 10, which has the first block 12 and the second block 13, is thick, regions, such as the recesses 14a and 14b and the grooves 18a and 18b, for holding sufficient amount of lubricant can be easily formed. Hence, even when a low-viscosity lubricant, such as vacuum oil, is used, the oil supply frequency can be reduced, and the maintenance cost can be reduced.

Although it is preferable that one roller R be accommodated in one roller retainer 10, two or more rollers R may be accommodated in one roller retainer 10. For example, a roller retainer for accommodating a plurality of rollers can be produced by machining, in a resin block having a rectangular-parallelepiped shape, a plurality of recesses corresponding to the roller accommodating parts.

In the above embodiment, the structure in which the projection 16 of one roller retainer 10 is engaged with the engaging groove 17 of another roller retainer 10 to connect the roller retainers 10 to each other has been described. However, the connecting structure of the roller retainers 10 is not limited thereto.

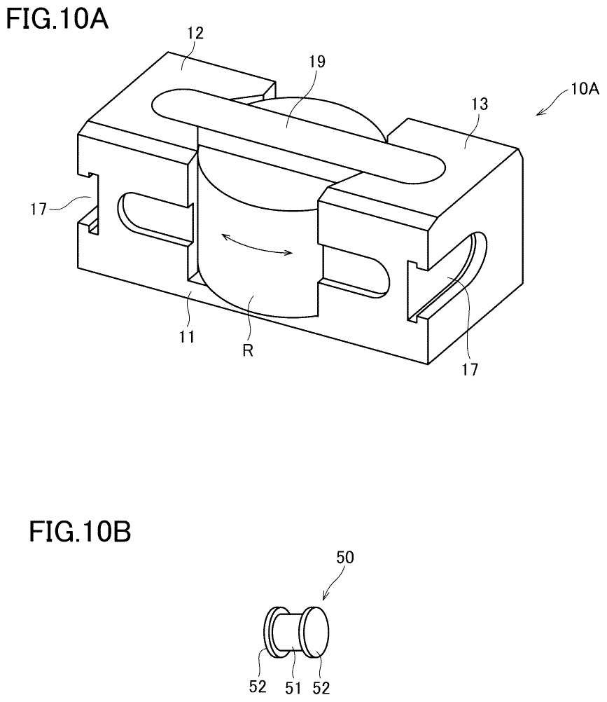

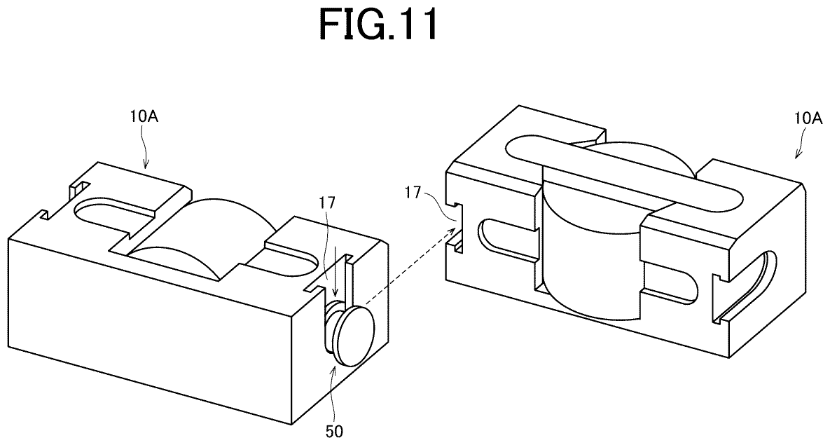

For example, as illustrated in FIG. 10A, a roller retainer 10A that does not have the projection 16 and has the engaging grooves 17 (connectors) in the outer end faces of the first block 12 and the second block 13 in the longitudinal direction may be formed. Such roller retainers 10A may be connected to each other using a connecting part 50, as illustrated in FIG. 10B.

The connecting part 50 includes a columnar shaft 51 and flange parts 52 provided at the ends of the shaft 51.

As illustrated in FIG. 11, one flange part 52 of the connecting part 50 is engaged with the engaging groove 17 of one roller retainer 10A. Then, the other flange part 52 of the connecting part 50 is engaged with the engaging groove 17 of another roller retainer 10A. The roller retainers 10A can be connected to each other in this way.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A roller-retainer connected body formed by connecting a plurality of roller retainers each accommodating a roller to one another, each roller retainer
including a base part, a first block provided at one end of the base part, and a second block provided at the other end of the base part,
accommodating a roller in a roller accommodating part between the first block and the second block, and
having a connector provided on each of an outer end face of the first block and an outer end face of the second block,
wherein the connectors of the plurality of roller retainers are connected to each other such that the rollers accommodated in the roller accommodating parts of the plurality of roller retainers rotate on different axes including rotation around a connecting axis.

2. The roller-retainer connected body according to claim 1, wherein
the connector provided on the outer end face of the first block is a projection,
the connector provided in the outer end face of the second block is an engaging groove, the engaging groove being formed so as to extend in a direction orthogonal to a rotation axis of the roller, and
the projection and the engaging groove of the plurality of roller retainers are connected to each other.

3. The roller-retainer connected body according to claim 1, wherein recesses for holding lubricant are formed in side surfaces of the first block and the second block.

4. The roller-retainer connected body according to claim 2, wherein recesses for holding lubricant are formed in side surfaces of the first block and the second block.

5. The roller-retainer connected body according to claim 1, wherein each of the plurality of roller retainers is movable in a direction of a radial load applied by traveling of one of a pair of guide rails.

6. The roller-retainer connected body according to claim 2, wherein each of the plurality of roller retainers is movable in a direction of a radial load applied by traveling of one of a pair of guide rails.

7. A cross roller guide comprising:
a pair of guide rails arranged in parallel and having V-grooves in opposing surfaces thereof; and
the roller-retainer connected body according to claim 1, disposed between the guide rails.

8. A stage device comprising:
the cross roller guide according to claim 7;
a fixed plate connected to one of the pair of guide rails; and
a table connected to the other of the pair of guide rails and capable of moving horizontally.
